(19) United States
(12) Patent Application Publication
(10) Pub. No.: US 2011/0149518 A1
(43) Pub. Date: Jun. 23, 2011

(54) HEAT-TRANSFER ARRANGEMENT FOR ENCLOSED CIRCUIT BOARDS

(75) Inventors: Todd R. Salamon, Summit, NJ (US); Paul R. Kolodner, Hoboken, NJ (US)

(73) Assignee: ALCATEL-LUCENT USA INC., Murray Hill, NJ (US)

(21) Appl. No.: 12/641,821

(22) Filed: Dec. 18, 2009

(51) Int. Cl. H05K 7/20

(52) U.S. Cl. 361/704

(57) ABSTRACT

An electronics module designed to efficiently remove heat from enclosed circuit boards via one or more configurable heat conduits. Each heat conduit is custom-configured to provide good thermal contact between the corresponding heat-generating electronic device of an enclosed circuit board and the clamshell housing that encloses the circuit board. Good thermal contact between the clamshell housing and the outer case of the electronic module facilitates efficient heat transfer to the finned exterior surface of the outer case, where the heat is dissipated into the ambient environment via thermal conduction, natural convection, forced convection, and/or thermal radiation. Depending on the topology of the circuit board and the individual characteristics of the electronic device to be cooled, the corresponding configurable heat conduit might be based on a nested heat-sink coupler, a fitted movable plug, or a flexible ribbon-shaped heat pipe.

### BACKGROUND

1. Field of the Invention

The present invention relates to cooling heat-generating electronic devices and, more specifically but not exclusively, to heat removal from enclosed circuit boards.

2. Description of the Related Art

This section introduces aspects that may help facilitate a better understanding of the invention(s). Accordingly, the statements of this section are to be read in this light and are not to be understood as admissions about what is in the prior art or what is not in the prior art.

A typical circuit board has a plurality of densely packed electronic devices mounted thereon, which results in a rather complicated overall surface topology of varying heights, shapes, and profiles. Moreover, circuit boards of different types normally have very different surface topologies. In a typical electronics module, multiple circuit boards of different types are mounted side by side inside an electronics case. To maintain electronic devices within an appropriate operating-temperature range and to prevent overheating from adversely affecting their speed, power, and useful lifespan, heat generated by the electronic devices during their operation needs to be removed from the electronics module. However, the complicated and varying surface topology of the circuit boards and their side-by-side mounting arrangement make it relatively difficult to remove the heat from the electronics module in a desired efficient manner.

### SUMMARY

Disclosed herein are various embodiments of an electronics module designed to efficiently remove heat from enclosed circuit boards via one or more configurable heat conduits. Each heat conduit is custom-configured to provide good thermal contact between the corresponding heat-generating electronic device of an enclosed circuit board and the clamshell housing that encloses the circuit board. Good thermal contact between the clamshell housing and the outer case of the electronic module facilitates efficient heat transfer to the finned exterior surface of the outer case, where the heat is dissipated into the ambient environment via thermal conduction, natural convection, forced convection, and/or thermal radiation. Depending on the topology of the circuit board and the individual characteristics of the electronic device to be cooled, the corresponding configurable heat conduit might be based on a nested heat-sink coupler, a fitted movable plug, or a flexible ribbon-shaped heat pipe.

According to one embodiment, provided is an electronics module comprising (I) a case having a chassis for mounting one or more circuit packs and (II) a first circuit pack mounted on the chassis and comprising a first clamshell housing and a first circuit board. The first clamshell housing at least partially encloses the first circuit board. The first circuit board comprises one or more electronic devices. The electronics module further comprises one or more configurable heat conduits, each configured to provide thermal conductive coupling between (i) a respective electronic device of the first circuit board and (ii) the first clamshell housing.

### BRIEF DESCRIPTION OF THE DRAWINGS

Other aspects, features, and benefits of various embodiments of the invention will become more fully apparent, by way of example, from the following detailed description and the accompanying drawings, in which:

FIG. 1 shows a three-dimensional perspective view of a circuit board having attached thereto three prior-art heat sinks;

FIGS. 2A-D show an electronics module according to one embodiment of the invention;

FIG. 3 shows a partial cross-sectional side view of a circuit pack from the electronics module of FIG. 2 having a heat conduit according to one embodiment of the invention;

FIG. 4 shows a partial cross-sectional side view of a circuit pack from the electronics module of FIG. 2 having a heat conduit according to another embodiment of the invention;

FIG. 5 shows a partial cross-sectional side view of a circuit pack from the electronics module of FIG. 2 having a heat conduit according to yet another embodiment of the invention; and

FIG. 6 illustrates a method of configuring the heat conduit of FIG. 5 according to one embodiment of the invention.

### DETAILED DESCRIPTION

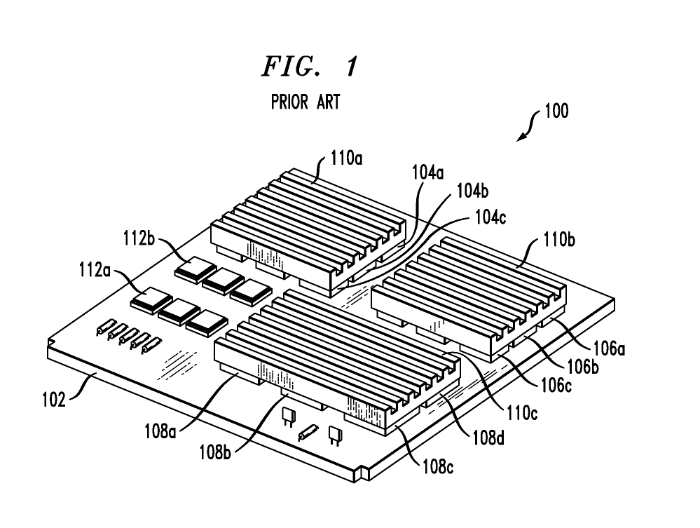

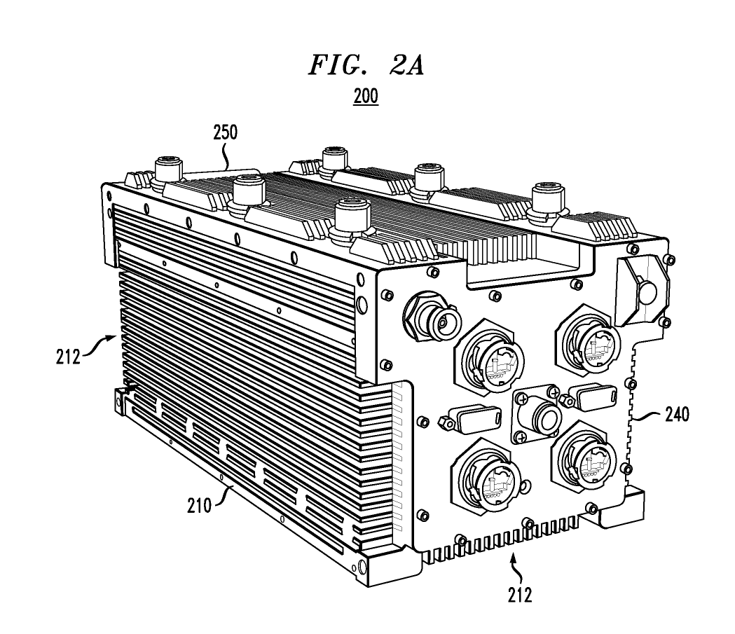

FIG. 1 shows a three-dimensional perspective view of a circuit board 100 having attached thereto three prior-art heat sinks 110a-c. More specifically, circuit board 100 comprises a plurality of electronic devices, e.g., integrated circuits, mounted on an epoxy-composite base board (e.g., printed wiring board, PWB) 102. Each heat sink 110 is attached to a corresponding group of devices, with all devices within the group preferably having similar shapes and dimensions. For example, heat sink 110a is attached to a group having nine devices 104; heat sink 110b is attached to a group having nine devices 106; and heat sink 110c is attached to a group having six devices 108. In addition, a heat sink similar to heat sink 110 can be attached to each individual heat-generating device, e.g., integrated circuit 112.

Each heat sink 110 is fabricated of a material having good thermal conductivity, e.g., aluminum or copper, and has the shape of a plate with fins extending from one side of the plate to increase the effective surface area for heat dissipation. The opposite side of the plate is appropriately profiled to match the geometric shape of the group being cooled. However, one problem with heat sink 110 is that it is not particularly suitable for use with enclosed circuit boards.

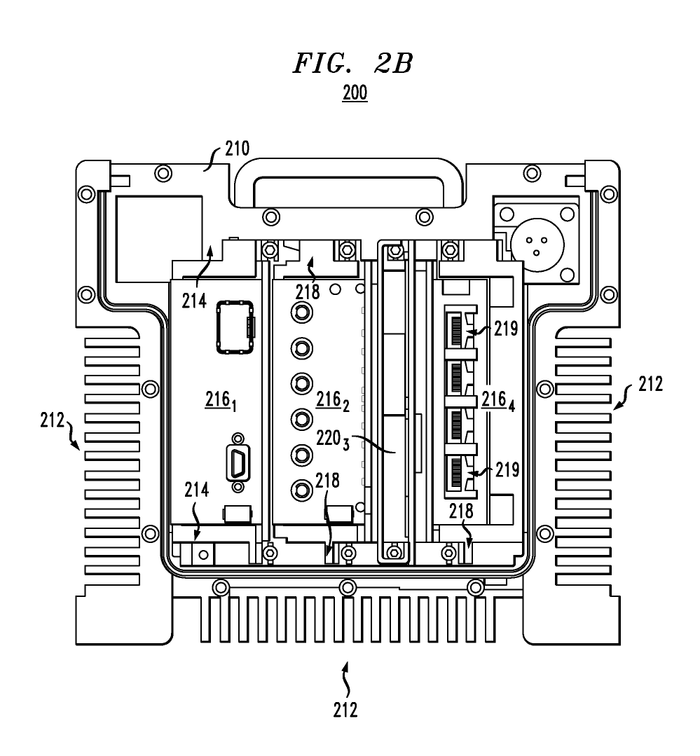

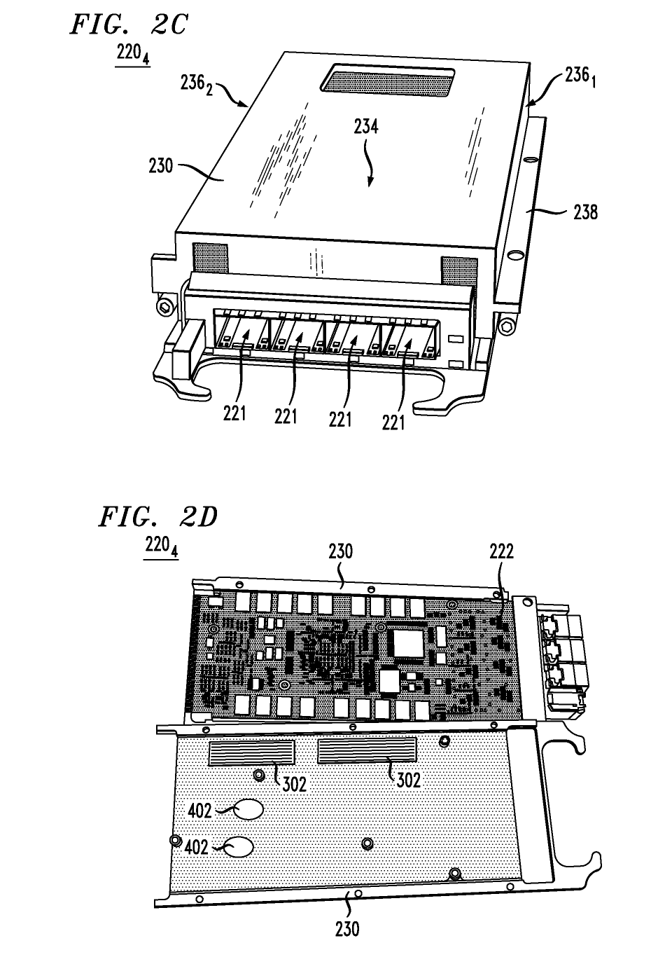

FIGS. 2A-D show an electronics module 200 according to one embodiment of the invention. More specifically, FIG. 2A shows a three-dimensional perspective view of electronics module 200. FIG. 2B shows a front view of electronics module 200, with a front plate 240 of the electronics module removed. FIG. 2C shows a circuit pack 220 pulled out of electronics module 200. FIG. 2D shows circuit pack 220 with its clamshell housing 230 open.

Referring to FIGS. 2A-B, electronics module 200 has an outer case 210 made of a material having relatively high thermal conductivity. Outer case 210 has a finned exterior comprising a plurality of fins 212, each having a relatively large surface area. Fins 212 increase the total exterior surface area of outer case 210 and facilitate heat dissipation from electronics module 200 into the ambient environment. In various embodiments, one or more sidewalls of outer case 210 might have a respective plurality of fins 212. For example, in the embodiment shown in FIG. 2A, four (i.e., left, right, top, and bottom) sidewalls of outer case 210 have fins 212. In an alternative embodiment, a different number of sidewalls of outer case 210 might have fins 212. In addition to serving as a heat sink, outer case 210 can be used to protect the equipment housed therein, e.g., from mechanical damage, dust, moisture, and tampering.

The interior of outer case 210 has a built-in chassis 214 for mounting one or more circuit packs 220. In the embodiment shown in FIG. 2B, chassis 214 has four circuit-pack slots 216₁-216₄, each designed to accommodate a respective one of circuit packs 220₁-220₄. For illustration purposes, chassis 214 is shown in FIG. 2B with all but one circuit pack 220 pulled out. The single remaining circuit-pack is circuit pack 220₃ positioned in circuit-pack slot 216₃. In an alternative embodiment, chassis 214 can have fewer or more than four circuit-pack slots 216.

Each circuit-pack slot 216 in chassis 214 has one or more guiding grooves 218 for sliding the corresponding circuit pack 220 into and out of the chassis. Guiding grooves 218 also serve to appropriately align circuit pack 220 with the electrical connectors located on front plate 240 and/or on a back plate 250 of outer case 210. Guiding groove(s) 218 in each particular circuit-pack slot 216 can be designed to securely support the corresponding circuit pack 220 in a position where the circuit pack has been slid out of chassis 214 substantially clear of the chassis' front edge. This feature of chassis 214 might be useful for inspection and maintenance of circuit packs 220, e.g., because it enables a service technician to conveniently slide a circuit pack out of the chassis, perform a desired procedure on it, and then slide the circuit pack back into the chassis. Circuit packs 220 and chassis 214 might have means (e.g., matching machine screws and threaded holes) for securely fastening the circuit packs to the chassis after the circuit packs have been slid into the chassis.

FIGS. 2C-D show circuit pack 220₄, which has been pulled out of circuit-pack slot 216₄ (also see FIG. 2B). This circuit pack is described in more detail below. Since each of circuit packs 220₁-220₃ is analogous to circuit pack 220₄, no special description of those circuit packs is given herein.

Clamshell housing 230 of circuit pack 220₄ at least partially encloses a circuit board 222 and is made of a material having relatively high thermal conductivity. In terms of shape, clamshell housing 230 substantially is a hollow rectangular box with one or more detachable sidewalls. Circuit board 222 is outfitted with electrical connectors 221 that stick out of the box. Electrical connectors 221 are complementary to electrical connectors 219 located on back plate 250 in circuit-pack slot 216₄ (also see FIGS. 2A-B). Guiding rail 238 of clamshell housing 230 fits into the corresponding guiding groove 218 of circuit-pack slot 216₄ and enables circuit pack 220₄ to be slid into and secured in that slot so that electrical connectors 221 are mated with electrical connectors 219.

Clamshell housing 230 has four substantially flat sidewalls 234 and 236. Sidewalls 234 correspond to the relatively wide sides of clamshell housing 230. In the view of FIG. 2B, sidewalls 234 are oriented vertically when circuit pack 220₄ is inserted into circuit-pack slot 216₄. Sidewalls 236 correspond to the relatively narrow sides of clamshell housing 230. Sidewall 236₁ has guiding rail 238, which extends out from that sidewall as indicated in FIG. 2C. Sidewall 236₂ might also have a guiding rail similar to guiding rail 238. In the view of FIG. 2B, sidewalls 236 are oriented horizontally when circuit pack 220₄ is inserted into circuit-pack slot 216₄.

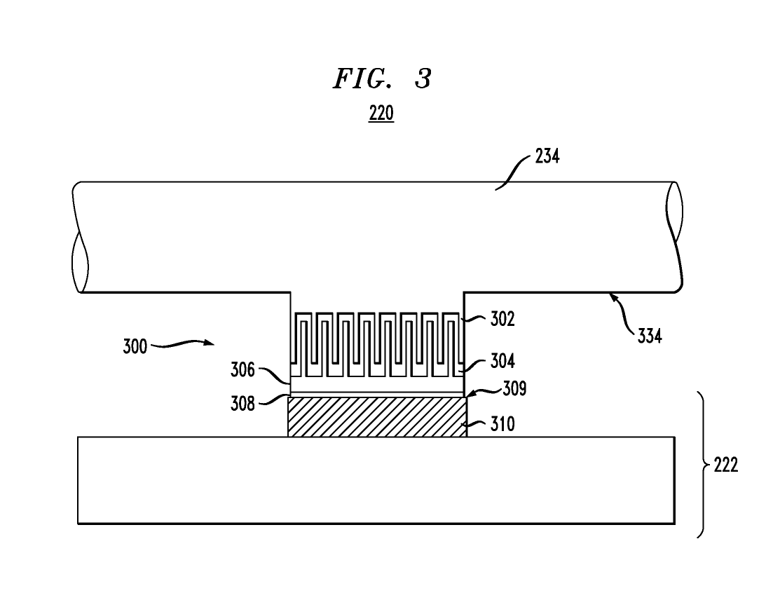

The electronic devices of circuit board 222 are similar to the electronic devices of circuit board 100 (see FIG. 1, devices 104-112) in that they create a complicated surface topology for the circuit board and generate heat during operation. In various embodiments, clamshell housing 230 has one or more adjustable and/or configurable components that can be used to conform the topology of the interior surface of the clamshell housing to the complicated surface topology of circuit board 222 and create efficient conduits for transferring heat from the heat-generating electronic devices of the circuit board to the clamshell housing. These adjustable/configurable heat conduits of clamshell housing 230 are described in more detail below in reference to FIGS. 3-6.

After being fully assembled (e.g., as shown in FIG. 2A), electronics module 200 provides the following heat-dissipation pathways for heat-generating electronic devices of various circuit packs 220. The one or more adjustable/configurable heat conduits of each clamshell housing 230 collect heat from electronic devices of the respective circuit board 222 and transfer it to the main body (e.g., sidewalls) of the clamshell housing. Each clamshell housing 230 then transfers the heat received through the heat conduits to outer case 210 and colder clamshell housings 230 (if any) of adjacent circuit packs 220. Finally, outer case 210 transfers the heat received from clamshell housings 230 to the ambient environment, e.g., via thermal conduction, natural convection, forced convection, and/or thermal radiation. In general, in various embodiments, outer case 210 can be designed to rely on any suitable modes of heat removal from the exterior of the case.

Clamshell housings 230 of various circuit packs 220 transfer heat to outer case 210, for example, as follows. Clamshell housing 230 of each circuit pack 220 transfers heat to outer case 210 through contact areas between (I) guiding rail(s) 238 of the clamshell housing and the surface of the corresponding guiding groove(s) 218 of chassis 214 and/or (II) narrow sidewalls 236 of the clamshell housing and the adjacent sidewalls of the outer case. Clamshell housings 230 of circuit packs 220₁ and 220₄ additionally transfer heat to outer case 210 through contact areas between wide sidewalls 234 of the clamshell housings and the adjacent sidewalls of the outer case (see FIGS. 2B-C).

Clamshell housings 230 of two adjacent circuit packs 220 can transfer heat to each other, e.g., through contact areas between their respective wide sidewalls 234.

The above-mentioned contact areas can be formed, e.g., by direct physical contact between the respective adjacent parts of circuit packs 220 and outer case 210. If machining tolerances are such that relatively narrow air gaps are present between some or all of the adjacent parts, then a thermal gap-filler material can be used to bridge those gaps as known in the art. A variety of suitable thermal gap-filler products of different texture and consistency are available on the market for this purpose. These products include, but are not limited to thermally conductive grease, putty, rubber, adhesive tape, and elastic pads. Each of these products has significantly higher thermal conductivity than air and can be selected to have desired mechanical and structural properties, thermal conductivity, electrical impedance, dielectric strength, etc.

FIG. 3 shows a partial cross-sectional side view of circuit pack 220 whose clamshell housing 230 (also see FIGS. 2C-D) has an adjustable/configurable heat conduit 300 according to one embodiment of the invention. More specifically, heat conduit 300 comprises a nested heat-sink (NHS) coupler having two interdigitated, finned heat-transfer blocks 302 and 306. Heat-transfer block 302 is part of or attached to sidewall 234 of clamshell housing 230 (also see FIG. 2D). Heat-transfer block 306 is attached to an electronic device (e.g., integrated circuit) 310 of circuit board 222 using a thin layer 308 of thermally conducting adhesive or solder. The fins of heat-transfer blocks 302 and 306 have dimensions that cause the gaps between the fin faces to be relatively narrow, e.g., smaller than about 0.1 mm. A layer 304 of thermal grease or other suitable compliant thermal gap-filler material is optionally used to fill those gaps.

The interdigitated fins enable heat-transfer blocks 302 and 306 to have a relatively large interface for good thermal contact while allowing for motion of the heat-transfer blocks with respect to one another. Such motion might include, but is not limited to translation, tilting, thermal expansion/contraction, and various types of deformation. The relative movability of heat-transfer blocks 302 and 306 is beneficial for several reasons. One reason is that it enables heat conduit 300 to accommodate some misalignment between clamshell housing 230 and circuit board 222. Another reason is that it limits the pressure/stress that can be exerted by clamshell housing 230 on electronic device 310, thereby reducing the risk of damage to that device during assembly, servicing, and/or operation of circuit pack 220.

The use of heat conduit 300 is most appropriate when the distance between an interior surface 334 of sidewall 234 and a top surface 309 of electronic device 310 is relatively large, e.g., larger than about 0.5 cm. Advantageously, heat-transfer characteristics of heat conduit 300 exceed those of conventional gap-filler materials by a relatively wide margin. For example, when heat-transfer blocks 302 and 306 are made of aluminum and have a combined height of about 1.3 cm, heat conduit 300 has thermal conductance that is about 50% of that of a similarly sized solid aluminum block. Additional embodiments of NHS couplers that can be adapted for use in circuit pack 220 in a manner similar to that of heat conduit 300 are described, e.g., in U.S. Patent Application Publication Nos. 2006/0087816 and 2006/0060328, both of which are incorporated herein by reference in their entirety.

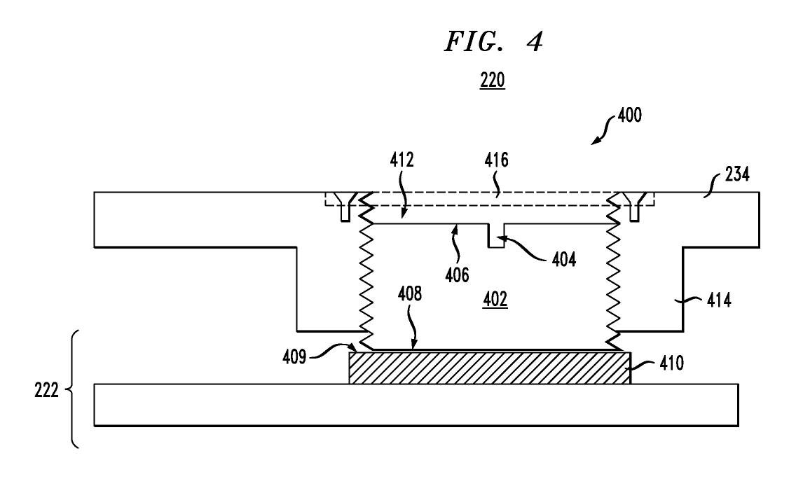

FIG. 4 shows a partial cross-sectional side view of circuit pack 220 whose clamshell housing 230 has an adjustable/configurable heat conduit 400 according to another embodiment of the invention. More specifically, heat conduit 400 comprises a threaded cylindrical plug 402 placed into a matching threaded cylindrical hole 412 in sidewall 234 (also see FIG. 2D). Cylindrical plug 402 can be turned similar to a screw, e.g., using a screwdriver slot 404, to bring a bottom surface 408 of the plug into direct physical contact with a top surface 409 of an electronic device 410 of circuit board 222. A thin layer of thermal grease (not explicitly shown) can optionally be used to further improve the thermal contact (i) between surfaces 408 and 409 and/or (ii) between the threaded sides of cylindrical plug 402 and hole 412. In one embodiment, sidewall 234 has a flange 414 around hole 412. In effect, flange 414 thickens sidewall 234 in the region immediately adjacent to hole 412 and electronic device 410. Flange 414 also causes the contact area between the threaded sides of cylindrical plug 402 and hole 412 to be relatively large, which facilitates efficient heat transfer from the cylindrical plug to the flange and then to sidewall 234.

In an alternative embodiment (not explicitly shown), plug 402 is modified to have (i) smooth (as opposed to threaded) sides and (ii) any selected (e.g., rectangular) transverse cross-sectional shape. The shape of hole 412 is similarly modified so that plug 402 can be press-fitted into the hole. The ability to have a plug with an arbitrary transverse cross-sectional shape might be beneficial because surfaces 408 and 409 can now be configured to match each other very accurately for more efficient heat removal from electronic device 410. A non-threaded plug 402 can be held in place, e.g., by placing an appropriate compressible elastic gap-filler pad in hole 412 next to a top surface 406 of the plug. Compression/confinement pressure can be applied to the gap-filler pad, e.g., by using (i) a sidewall 234 of adjacent circuit pack 220, (ii) a vertical sidewall of chassis 214 (see FIG. 2B), or (iii) a recessed retention plate 416 indicated by the dashed line in FIG. 4. The pressure keeps the elastic gap-filler pad in a compressed state and causes the pad to press movable plug 402 against electronic device 410.

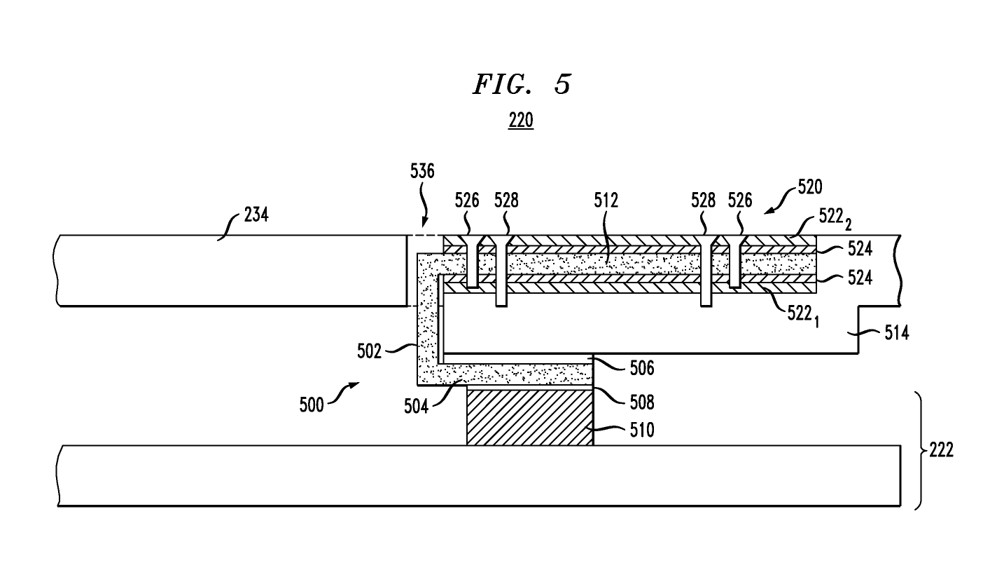

FIG. 5 shows a partial cross-sectional side view of circuit pack 220 whose clamshell housing 230 has an adjustable/configurable heat conduit 500 according to yet another embodiment of the invention. More specifically, heat conduit 500 comprises a flexible ribbon-shaped heat pipe 502. A suitable heat pipe that can be used as heat pipe 502 is commercially available, e.g., from American Furukawa, Inc., under the tradename “pera-flex.” A detailed description of pera-flex can be found, e.g., in an article published in Furukawa Review, 2004, No. 25, pp. 64-66, which article is incorporated herein by reference in its entirety.

As known in the art, a heat pipe is a heat-transfer device that relies on both thermal conduction and phase transitions of a working fluid to transport heat from a “hot” end of the heat pipe to its “cold” end. At the hot end, the working fluid undergoes a liquid/vapor phase transition, thereby absorbing heat. The vapor naturally flows toward the cold end, e.g., due to a pressure differential caused by different temperatures of the two ends. At the cold end, the vapor condenses back into a liquid, thereby releasing heat. The condensed liquid then flows back to the hot end, e.g., under capillary and/or gravitational forces. This cycle is repeated, thereby causing the heat pipe to continuously transport heat from the hot end to the cold end.

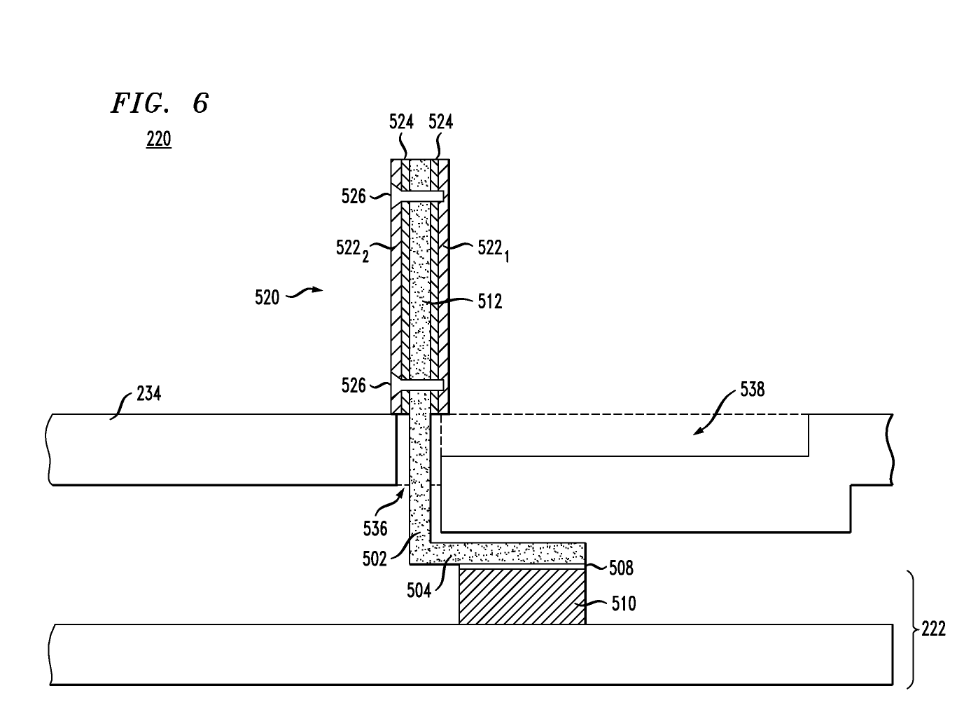

In heat conduit 500, ends 504 and 512 of heat pipe 502 are the hot and cold ends, respectively. End 504 is attached to an electronic device 510 of circuit board 222 using a thin layer 508 of thermally conducting adhesive or another suitable interface structure. End 512 is attached to sidewall 234 of clamshell housing 230 using a fixture 520, e.g., as described below in reference to FIG. 6. Heat conduit 500 might optionally have a layer 506 of thermal gap filler between hot end 504 of heat pipe 502 and a flange 514 of sidewall 234. The presence of layer 506 and flange 514 might be beneficial because they can increase the total heat-transfer rate in heat conduit 500.

FIG. 6 illustrates a method of configuring heat conduit 500 according to one embodiment of the invention. First, layer 508 is deposited over electronic device 510, and end 504 of heat pipe 502 is affixed to that layer. Heat pipe 502, which is initially shaped as a flat ribbon, is then bent, e.g., as shown in FIG. 6, and inserted into a slot 536 in sidewall 234 to place end 512 of the heat pipe outside clamshell housing 230. Fixture 520 is then attached to end 512 as indicated in FIG. 6. After fixture 520 has been attached, heat pipe 502 is bent again to place fixture 520 into a recess 538 in sidewall 234. Finally, fixture 520 is attached to sidewall 234 using machine screws 528 to produce the heat-conduit configuration shown in FIG. 5.

In one embodiment, fixture 520 comprises two plates 522₁-522₂ that sandwich, between them, end 512 of heat pipe 502. Plates 522₁-522₂ are fastened together using machine screws 526. Optional layers 524 of thermal grease or gap filler can be added to the sandwich structure, e.g., as indicated in FIG. 6, to bridge possible air gaps within fixture 520, thereby improving heat transfer between the fixture and heat pipe 502. An additional optional layer (not explicitly shown in FIGS. 5-6) of thermal grease or gap filler can be placed at the interface between plate 522₁ and sidewall 234 to increase the heat-transfer rate between fixture 520 and the sidewall.

In an alternative embodiment, fixture 520 can be replaced by other suitable means for attaching end 512 of heat pipe 502 to a surface of sidewall 234. Such means might include one or more of: adhesive layers, thermal gap fillers, retention plates, screw assemblies, etc. For example, according to one of such alternative embodiments, the top face of end 512 of heat pipe 502 is coated with a thin layer of thermal grease to maximize thermal contact with the underside of the external structure to which the heat is to be transferred (e.g., outer case 210). The bottom face of end 512 is pressed down against a compliant thermal gap-filler pad lying on the bottom of recess 538. The gap-filler pad serves mostly to push the top face of heat pipe 502 against the bottom face of the exterior structure, for more efficient heat transfer.

As used herein, the term “case” should be construed to cover any suitable container, such as an electronics crate, rack, box, cabinet, console, and enclosure. Such container might be equipped with any suitable means for dissipating heat transferred to the body of the container from its interior, with said means being used instead of or in addition to a finned exterior surface analogous to that defined by fins 212.

As used herein, the terms “thermal conductive coupling” and “thermally conductively coupled” refer to the ability to conduct heat, from one structural element to another, through direct physical contact between those two elements or through one or more intervening structures that physically connect those two elements. Generally, thermal conductivity is an intrinsic property of a material or structure, which involves transfer of heat within the material or structure without any macroscopic motion of the material or structure as a whole. Heat conduction takes place when a temperature gradient exists in a solid or stationary fluid medium. Conductive heat flow occurs in the direction of decreasing temperature because energy is transferred from more energetic atoms or molecules to less energetic ones. Heat transfer by radiation is generally considered to be a separate phenomenon, different from heat conduction.

While this invention has been described with reference to illustrative embodiments, this description is not intended to be construed in a limiting sense. Although chassis 214 and clamshell housing 230 have been described as having guiding groove 218 and guiding rail 238, the use of other suitable attachment mechanisms is also possible. Various modifications of the described embodiments, as well as other embodiments of the invention, which are apparent to persons skilled in the art to which the invention pertains are deemed to lie within the principle and scope of the invention as expressed in the following claims.

Unless explicitly stated otherwise, each numerical value and range should be interpreted as being approximate as if the word “about” or “approximately” preceded the value of the value or range.

It will be further understood that various changes in the details, materials, and arrangements of the parts which have been described and illustrated in order to explain the nature of this invention may be made by those skilled in the art without departing from the scope of the invention as expressed in the following claims.

The use of figure numbers and/or figure reference labels in the claims is intended to identify one or more possible embodiments of the claimed subject matter in order to facilitate the interpretation of the claims. Such use is not to be construed as necessarily limiting the scope of those claims to the embodiments shown in the corresponding figures.

Although the elements in the following method claims, if any, are recited in a particular sequence with corresponding labeling, unless the claim recitations otherwise imply a particular sequence for implementing some or all of those elements, those elements are not necessarily intended to be limited to being implemented in that particular sequence.

Reference herein to “one embodiment” or “an embodiment” means that a particular feature, structure, or characteristic described in connection with the embodiment can be included in at least one embodiment of the invention. The appearances of the phrase “in one embodiment” in various places in the specification are not necessarily all referring to the same embodiment, nor are separate or alternative embodiments necessarily mutually exclusive of other embodiments. The same applies to the term “implementation.”

Throughout the detailed description, the drawings, which are not to scale, are illustrative only and are used in order to explain, rather than limit the invention. The use of terms such as height, length, width, top, bottom, is strictly to facilitate the description of the invention and is not intended to limit the invention to a specific orientation. For example, height does not imply only a vertical rise limitation, but is used to identify one of the three dimensions of a three dimensional structure as shown in the figures.

Also for purposes of this description, the terms “couple,” “coupling,” “coupled,” “connect,” “connecting,” or “connected” refer to any manner known in the art or later developed in which energy is allowed to be transferred between two or more elements, and the interposition of one or more additional elements is contemplated, although not required. Conversely, the terms “directly coupled,” “directly connected,” etc., imply the absence of such additional elements.

All statements herein reciting principles, aspects, and embodiments of the invention, as well as specific examples thereof, are intended to encompass equivalents thereof.

What is claimed is:

1. Apparatus, comprising:
a case having a chassis for mounting one or more circuit packs;
a first circuit pack mounted on the chassis and comprising a first clamshell housing and a first circuit board, wherein:
the first clamshell housing at least partially encloses the first circuit board; and
the first circuit board comprises one or more electronic devices; and
one or more configurable heat conduits, each configured to provide thermal conductive coupling between (i) a respective electronic device of the first circuit board and (ii) the first clamshell housing.

2. The invention of claim 1, wherein:
the one or more configurable heat conduits are adapted to (i) collect heat generated by the one or more electronic devices of the first circuit board and (ii) transfer the collected heat to the first clamshell housing;
the first clamshell housing is adapted to transfer at least a portion of the heat received via the one or more configurable heat conduits to the case; and
the case is adapted to dissipate received heat into ambient environment.

3. The invention of claim 1, wherein the case comprises:
a finned exterior surface; and
a plate having one or more electrical connectors that are complementary to respective one or more electrical connectors of the first circuit pack.

4. The invention of claim 1, wherein:
the first clamshell housing is attached to the chassis via an attachment mechanism; and
the case and the first clamshell housing are thermally conductively coupled to one another through said attachment mechanism.

5. The invention of claim 4, wherein:
the first clamshell housing comprises a first sidewall; and
the case and the first clamshell housing are further thermally conductively coupled through the first sidewall and an interior surface of the case.

6. The invention of claim 5, wherein:
the attachment mechanism comprises:
a guiding groove formed in the chassis; and
a guiding rail slidable along the guiding groove and extending outward from the first sidewall; and
the case and the first clamshell housing are thermally conductively coupled through the guiding rail and a surface of the guiding groove.

7. The invention of claim 5, wherein:
the first clamshell housing comprises a second sidewall orthogonal to the first sidewall;
the case and the first clamshell housing are further thermally conductively coupled through the second sidewall and the interior surface of the case.

8. The invention of claim 1, wherein:
the first clamshell housing comprises a sidewall; and
the case and the first clamshell housing are thermally conductively coupled through the sidewall and an interior surface of the case.

9. The invention of claim 1, further comprising a second circuit pack that comprises a second clamshell housing and a second circuit board, wherein the second circuit pack is mounted on the chassis so that an external surface of the first clamshell housing and an external surface of the second clamshell housing are adjacent to one another.

10. The invention of claim 9, wherein:
the second clamshell housing at least partially encloses the second circuit board;
the second circuit board comprises one or more electronic devices;
the apparatus further comprises one or more additional configurable heat conduits, each configured to provide thermal conductive coupling between (i) a respective electronic device of the second circuit board and (ii) the second clamshell housing;
the one or more additional configurable heat conduits are adapted to (i) collect heat generated by the one or more electronic devices of the second circuit board and (ii) transfer the collected heat to the second clamshell housing;
the second clamshell housing is adapted to transfer at least a portion of the heat received via the one or more configurable heat conduits to the first clamshell housing through said external surfaces; and
the first clamshell housing is adapted to transfer at least a portion of the heat received from the second clamshell housing to the case; and
the case is adapted to dissipate received heat into ambient environment.

11. The invention of claim 1, wherein a first configurable heat conduit from the one or more configurable heat conduits comprises:
a first finned block attached to an electronic device of the first circuit board; and
a second finned block that is part of or attached to a sidewall of the first clamshell housing, wherein fins of the first finned block are interdigitated with fins of the second finned block.

12. The invention of claim 11, wherein the first configurable heat conduit further comprises a layer of compliant thermal gap-filler material that fills gaps between the interdigitated fins.

13. The invention of claim 1, wherein a first configurable heat conduit from the one or more configurable heat conduits comprises a movable plug fitted into a hole in a sidewall of the first clamshell housing and positioned to be in physical contact with an electronic device of the first circuit board.

14. The invention of claim 13, wherein the movable plug has a thread that matches a thread of the hole.

15. The invention of claim 13, wherein:
the first configurable heat conduit further comprises a flange that is part of or attached to the sidewall;
the flange has a hole that is an extension of the hole in the sidewall; and
the movable plug is fitted into the hole in the flange.

16. The invention of claim 13, wherein the first configurable heat conduit further comprises:
a retention plate attached to the sidewall so as to at least partially cover the hole; and
an elastic gap-filler pad located between the retention plate and the movable plug, wherein the elastic gap-filler pad is in a compressed state to press the movable plug against the electronic device.

17. The invention of claim 1, wherein a first configurable heat conduit from the one or more configurable heat conduits comprises a flexible heat pipe having a first end and a second end, wherein:
the first end is thermally conductively coupled to an electronic device of the first circuit board; and
the second end is thermally conductively coupled to a sidewall of the first clamshell housing.

18. The invention of claim 17, wherein:
the first configurable heat conduit further comprises a fixture attached to the second end and further attached to the sidewall to thermally couple the second end and the sidewall; and
the flexible heat pipe protrudes through a hole or slot in the sidewall.

19. The invention of claim 17, wherein the first configurable heat conduit further comprises:
a flange that is part of or attached to the sidewall; and
a layer of thermal gap-filler material that bridges a gap between the first end and the flange.

20. The invention of claim 1, wherein:
a first configurable heat conduit from the one or more configurable heat conduits is configured to provide thermal conductive coupling between (i) a first electronic device of the first circuit board and (ii) the first clamshell housing;
a second configurable heat conduit from the one or more configurable heat conduits is configured to provide thermal conductive coupling between (i) a second electronic device of the first circuit board and (ii) the first clamshell housing;
the first electronic device has a first shape and a first offset distance from a base board of the first circuit board;
the second electronic device has a second shape and a second offset distance from the base board; and
the first and second electronic devices have at least one of the following two characteristics:
(1) the first shape is different from the second shape; and
(2) the first offset distance is different from the second offset distance.
